(19) United States
(12) Patent Application Publication
(10) Pub. No.: US 2026/0244960 A1
(43) Pub. Date: Aug. 20, 2026

(54) INTELLIGENT IDENTIFICATION METHOD AND SYSTEM FOR PARTIAL DISCHARGE BASED ON COLLABORATIVE REASONING

(71) Applicants: Linyi University, Linyi City (CN); The University of Suwon, Hwaseong-si (SK)

(72) Inventors: Zunwei FU, Linyi City (CN); Congcong ZHANG, Linyi City (CN)

(73) Assignees: Linyi University, Linyi City, SD (CN); The University of Suwon, Hwaseong-si, GG (SK)

(21) Appl. No.: 19/565,884

(22) Filed: Mar. 13, 2026

(30) Foreign Application Priority Data
Jul. 11, 2025 (CN) 202510954065.8

(51) Int. Cl. G06N 5/048; G01R 31/12

(52) U.S. Cl. CPC G06N 5/048; G01R 31/1272

(57) ABSTRACT

An intelligent identification method and system for partial discharge based on collaborative reasoning are provided, and belong to the field of partial discharge detection. The semantic structure of high-dimensional PD data is explicitly deconstructed through the construction of multi-scale feature information map and sparse spectrum division algorithm, and the feature subchannels strongly related to the discharge mechanism are separated, thus the semantic interference in the field data is effectively suppressed. Furthermore, the fuzzy modeler induced by channel structure is used to learn local rule sets independently, and combine with the dynamic fusion mechanism driven by cross-channel prediction consistency, so that the tolerance to voltage phase loss, background noise disturbance and equipment heterogeneity is significantly improved.

### CROSS-REFERENCE TO RELATED APPLICATIONS

This application claims priority of Chinese Patent Application No. 202510954065.8, filed on Jul. 11, 2025, the content of which is hereby incorporated by reference.

### TECHNICAL FIELD

The disclosure relates to the technical field of partial discharge detection, and in particular to an intelligent identification method and system for partial discharge based on collaborative reasoning.

### BACKGROUND

Partial discharge (PD) identification is the core means of insulation state monitoring of power equipment. Traditional methods rely on clean voltage-discharge synchronous signals in laboratory environment, and adopt neural network or fuzzy system for pattern classification. This kind of technology performs well in controlled environment, such as GIS partial discharge identification based on fractal features (such as box dimension and information dimension) (see the patent CN 104155585 A). However, the challenge of multi-source heterogeneous data under field conditions exists: the difference of sensor models, changeable installation methods, diverse cable types and fluctuation of operating voltage lead to significant deviation of data distribution structure. More importantly, the voltage phase label is often missing in field measurement, and the information is used as a key input feature in laboratory models, which leads to a serious decline in the generalization ability of existing models when deployed in the field.

At present, there are four limitations in PD identification methods: firstly, there are a large number of semantic interference subchannels in high-dimensional measurement data, but the existing models lack dynamic channel-level structure modeling mechanism, which may not effectively separate interference; secondly, the coupling structure differences of different discharge types (such as corona discharge and suspended matter discharge) in the feature dimension are not considered, which leads to insufficient feature expression ability; thirdly, the traditional fuzzy reasoning rules and feature groups lack collaboration, and the generalization ability of rules is limited, so it is difficult to adapt to the complex noise background in the field; fourthly, the existing framework may not deal with the inherent problems in the field, such as the lack of voltage phase and strong background noise. For example, the case patent relies on power frequency cycle segmentation to extract semi-periodic fractal features, but the scheme fails when there is no phase label in the field. These problems lead to high identification error rate and low tolerance of unknown patterns, which seriously restricts engineering practicability.

Therefore, it is urgent to construct a new identification framework that takes into account the structural deconstruction ability and the fuzzy reasoning collaboration, so as to solve the special challenges in high-dimensional heterogeneous data, such as semantic interference separation, cross-device data distribution deviation, voltage phase loss and so on, and improve the portability and robustness of the model.

### SUMMARY

The disclosure aims to provide an intelligent identification method and system for partial discharge based on collaborative reasoning, so as to solve the problems existing in the prior art.

In order to achieve the above purpose, the disclosure provides the following scheme:
an intelligent identification method for partial discharge based on collaborative reasoning is provided, and includes:
S1, constructing a multi-scale feature information map of partial discharge measurement data, and extracting inter-dimensional high-order dependencies;
S2, dividing a high-dimensional feature space into multiple structural consistency feature subchannels by a structural decomposition algorithm, where each of the subchannels corresponds to a local feature group related to a discharge mechanism;
S3, independently constructing a fuzzy reasoning model for each of the feature subchannels, and generating channel-level discharge pattern sub-classifiers;
S4, dynamically adjusting fusion strategy based on prediction confidence, and performing structural consistency-driven fusion on outputs of the plurality of sub-classifiers; and
S5, outputting a final partial discharge type identification result.

Preferably, in S1, the multi-scale feature information map adopts at least one of mutual information, a GraphLasso algorithm, kernel correlation coefficients or a Copula function to construct inter-dimensional dependencies.

Preferably, in S2, the structural decomposition algorithm is a sparse spectrum division algorithm, a hierarchical Louvain clustering algorithm or an adaptive multi-channel clustering algorithm.

Preferably, in S3, the fuzzy reasoning model is constructed by automatically learning fuzzy rule sets and membership function structures.

Preferably, in S3, the fuzzy reasoning model is capable of being replaced by a sparse bayesian regression model or an ensemble fuzzy network model.

Preferably, in S4, the dynamically adjusting fusion strategy includes:
calculating prediction confidence of each of the sub-classifiers;
performing weighted fusion output according to confidence weight; and
performing fault-tolerant mechanism on inconsistencies among feature channels.

Preferably, in S4, a fused mechanism is capable of being replaced by a multi-task attention distribution model or a confidence regression network optimization weighting strategy.

Preferably, in S5, the identification result supports non-exclusive fuzzy classification of unknown or boundary discharge patterns.

An intelligent identification system for partial discharge based on collaborative reasoning is further provided, and includes:
a feature map construction module, configured for constructing a multi-scale feature information map of partial discharge measurement data, and extracting inter-dimensional high-order dependencies;
a channel dividing module, configured for dividing a high-dimensional feature space into multiple structural consistency feature subchannels by a structural decomposition algorithm, where each of the subchannels corresponds to a local feature group related to a discharge mechanism;
a fuzzy reasoning module, configured for independently constructing a fuzzy reasoning model for each of the feature subchannels, and generating channel-level discharge pattern sub-classifiers; and
a dynamic fusion module, configured for dynamically adjusting fusion strategy based on prediction confidence, and performing structural consistency-driven fusion on outputs of the plurality of sub-classifiers.

Preferably, the dynamic fusion module has a built-in cross-channel prediction consistency checking mechanism, triggering a confidence re-weighting process for conflicting outputs.

Compared with the prior art, the disclosure has the following beneficial technical effects.

The intelligent identification method and system for partial discharge based on collaborative reasoning provided by the disclosure explicitly deconstruct the semantic structure of high-dimensional PD data through the construction of multi-scale feature information map and sparse spectrum division algorithm, and separate the feature subchannels strongly related to the discharge mechanism, thus effectively suppressing the semantic interference in the field data. Furthermore, the fuzzy modeler induced by channel structure is used to learn local rule sets independently, and combine with the dynamic fusion mechanism driven by cross-channel prediction consistency, so that the tolerance to voltage phase loss, background noise disturbance and equipment heterogeneity is significantly improved. Compared with the traditional neuro-fuzzy model, this method realizes the non-exclusive fuzzy classification of unknown discharge patterns while maintaining interpretability, and solves the problem of model failure caused by data distribution deviation in field deployment, which obviously reduces the identification error rate and provides a highly robust solution for intelligent diagnosis of power equipment.

### BRIEF DESCRIPTION OF THE DRAWINGS

In order to explain the embodiments of the disclosure or the technical scheme in the prior art more clearly, the drawings needed in the embodiments will be briefly introduced below. Obviously, the drawings in the following description are only some embodiments of the disclosure. For ordinary skilled in the field, other drawings may be obtained according to these drawings without creative efforts.

FIG. 1 is a flowchart of an intelligent identification method for partial discharge based on collaborative reasoning according to embodiments of the disclosure.

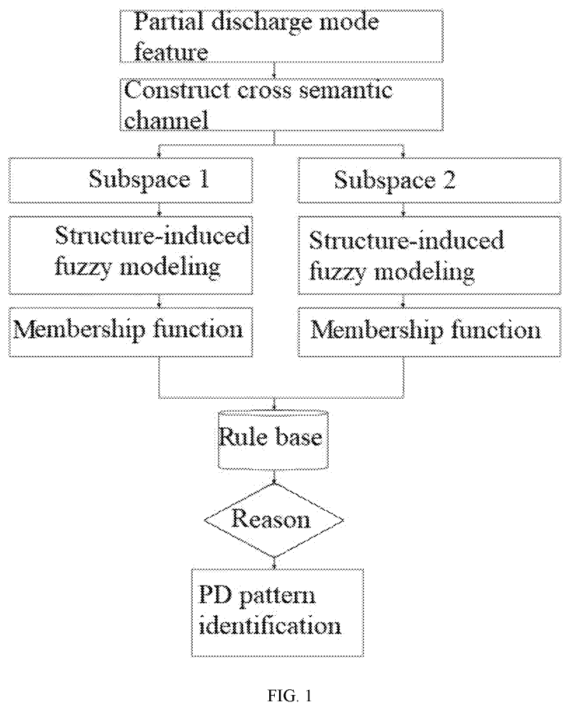

### DETAILED DESCRIPTION OF THE EMBODIMENTS

In the following, the technical scheme in the embodiment of the disclosure will be clearly and completely described with reference to the attached drawings in the embodiment of the disclosure. Obviously, the described embodiment is only a part of the embodiments of the disclosure, but not all the embodiments. Based on the embodiments in the disclosure, all other embodiments obtained by ordinary skilled in the field without creative efforts belong to the scope of protection of the disclosure.

The disclosure aims to provide an intelligent identification method and system for partial discharge based on collaborative reasoning, so as to solve the problems existing in the prior art.

In order to make the above purposes, features and advantages of the disclosure more obvious and easy to understand, the disclosure will be further described in detail with the attached drawings and specific embodiments.

### Embodiment 1

An intelligent identification method for partial discharge based on collaborative reasoning is provided, and includes the following methods.
S1, a multi-scale feature information map of partial discharge measurement data is constructed, and inter-dimensional high-order dependencies are extracted;
firstly, a mutual information matrix M∈ [symbol] is constructed;
Mᵢⱼ=I(X_{:,i};X_{:,j}) or other structural metrics (Copula, GraphLasso, etc.);
secondly, the Laplace matrix is used to calculate, so as to obtain:

$${D}_{ii} = {\sum }_{j} {M}_{ij} , L = D - M .$$

S2, a high-dimensional feature space is divided into multiple structural consistency feature subchannels by a structural decomposition algorithm, where each of the subchannels corresponds to a local feature group related to a discharge mechanism;
firstly, the spectral decomposition is performed on L, and the first K feature vectors are taken to construct a matrix U∈ [symbol] ;
secondly, each line (corresponding to each feature) in U is clustered to obtain K semantic channels:

$${C}_{k} ⊂ \{ 1 , 2 , … , d \} , {⋃}_{k = 1}^{K} {C}_{k} = \{ 1 , 2 , … , d \} ;$$

output: a channel partition set {C₁, C₂, . . . , C_{K}}.
S3, a fuzzy reasoning model for each of the feature subchannels is independently constructed, fuzzy rule sets and membership function structures are automatically learned, and channel-level discharge pattern sub-classifiers are generated;
for each channel k=1, . . . , K: firstly, subspace features are extracted:

$${X}^{( k )} = X [ : , {C}_{k} ] ∈ {ℝ}^{N \times \vert {C}_{k} \vert} ;$$

secondly, the TSK fuzzy model of each type of c=1, . . . , m is constructed, which has Rₖ rules:
Gaussian membership function of rule r:

$${μ}_{rj}^{( k )} ( {x}_{j} ) = exp ( - \frac{{( {x}_{j} - {c}_{rj} )}^{2}}{2 {σ}_{rj}^{2}} ) ;$$

activation intensity is:

$${w}_{r}^{( k )} ( x ) = {\prod }_{j ∈ {C}_{k}} {μ}_{rj}^{( k )} ( {x}_{j} ) ;$$

further, the output of each class C is:

$${f}_{r , c}^{( k )} ( x ) = {a}_{r , c}^{( k ) T} {x}^{( k )} + {b}_{r , c}^{( k )} ;$$

furthermore, the output of the channel to class C is weighted aggregation:

$${\hat{y}}_{k , c} ( x ) = \frac{{\sum }_{r = 1}^{{R}_{k}} {w}_{r}^{( k )} ( x ) \cdot {f}_{r , c}^{( k )} ( x )}{{\sum }_{r = 1}^{{R}_{k}} {w}_{r}^{( k )} ( x )} ;$$

finally, all categories output component vectors:

$${\hat{y}}_{k} ( x ) = [ {\hat{y}}_{k , 1} ( x ) , ... , {\hat{y}}_{k , m} ( x ) ] ∈ {ℝ}^{m} .$$

S4, fusion strategy is dynamically adjusted based on prediction confidence, and structural consistency-driven fusion is performed on outputs of the plurality of sub-classifiers:

firstly, the channel model prediction difference degree is calculated:

$${Dis}_{k} ( x ) = {‖ {\hat{y}}_{k} ( x ) - \overline{y} ( x ) ‖}_{2} , \overline{y} ( x ) = \frac{1}{K} {\sum }_{k = 1}^{K} {\hat{y}}_{k} ( x ) ;$$

secondly, weight distribution is performed;
if

$${max}_{k} {Dis}_{k} ( x ) > δ$$

(big prediction conflict), contrast weighting is used:

$${ω}_{k} ( x ) = \frac{1 / {Dis}_{k} ( x )}{{\sum }_{j} 1 / {Dis}_{j} ( x )} ;$$

otherwise, channel confidence weighting is used:

$${σ}_{k}^{2} = Var ( {\hat{y}}_{k} ) , {α}_{k} = exp ( - {σ}_{k}^{2} ) , {ω}_{k} = \frac{{α}_{k}}{{\sum }_{j} {α}_{j}} ;$$

further, the multi-output fusion is:

$$\hat{y} ( x ) = {\sum }_{k = 1}^{K} {ω}_{k} ( x ) \cdot {\hat{y}}_{k} ( x ) .$$

S5, a final partial discharge type identification result is outputted:
firstly, the final output is a multi-dimensional category vector:

$$\hat{y} ( x ) = [ {\hat{y}}_{1} ( x ) , {\hat{y}}_{2} ( x ) , ... , {\hat{y}}_{m} ( x ) ] ;$$

where, m is the number of categories;
secondly, hard classification output (main output path): the classification decision is made directly through the maximum value:

$$\hat{c} ( x ) = arg {max}_{j} {\hat{y}}_{j} ( x ) ;$$

this output mode is suitable for the standard single label classification task, and may be combined with softmax for probability interpretation:

$$P ( y = c \vert x ) = \frac{exp ( {\hat{y}}_{c} ( x ) )}{{\sum }_{j = 1}^{m} exp ( {\hat{y}}_{j} ( x ) )} ;$$

further, the fuzzy label interpretation may be selected (for boundary sample analysis and non-exclusive reasoning): in order to enhance the explanatory ability to model uncertainty to sample and fuzzy boundaries among classes, the predicted output ŷ_{c}(x) may be compared with the class mean ŷ_{c} to construct a “fuzzy response” function:

$${μ}_{c} ( x ) = \frac{1}{Z} exp ( - \frac{{( {\hat{y}}_{c} ( x ) - {\overline{y}}_{c} )}^{2}}{2 {τ}^{2}} ) , Z = {\sum }_{j = 1}^{m} exp ( ... ) ;$$

where, μ_{c}(x)∈[0,1] represents the “fuzzy response strength” or “similarity” of samples to classes c; τ represents the control response width (fuzziness); Z represents the normalization factor.

As one embodiment, in S1, the multi-scale feature information map adopts mutual information. Of course, besides mutual information, at least one of a GraphLasso algorithm, kernel correlation coefficients or a Copula function may be used to construct inter-dimensional dependencies.

As one embodiment, in S2, the structural decomposition algorithm is a sparse spectrum division algorithm, and of course, it may also be replaced by hierarchical Louvain clustering, adaptive multi-channel clustering and other methods.

As one embodiment, in S3, the fuzzy inference model may be replaced by a sparse Bayesian regression model or an ensemble fuzzy network model.

As one embodiment, in S4, the dynamically adjusting fusion strategy includes:
prediction confidence of each of the sub-classifiers is calculated;
weighted fusion output is performed according to confidence weight; and
fault-tolerant mechanism is performed on inconsistencies among feature channels.

As one embodiment, in S4, a fused mechanism is capable of being replaced by a multi-task attention distribution model or a confidence regression network optimization weighting strategy.

As one embodiment, in S5, the identification result supports non-exclusive fuzzy classification of unknown or boundary discharge patterns.

The fundamental difference between the disclosure and the traditional method lies in that, instead of “black box” modeling based on the overall features, the structural semantic fragments (channels) in PD data are explicitly extracted, and the expression ability, migration ability and tolerance ability to on-site defect signals of the model are improved through independent modeling and reasoning hierarchy fusion strategy. In addition, this method naturally supports interpretable reasoning under the condition of “weak supervision” and is of great practical value to engineering deployment.

### Embodiment 2

An intelligent identification system for partial discharge based on collaborative reasoning is provided, and includes:
a feature map construction module, configured for constructing a multi-scale feature information map of partial discharge measurement data, and extracting inter-dimensional high-order dependencies;
a channel dividing module, configured for dividing a high-dimensional feature space into multiple structural consistency feature subchannels by a structural decomposition algorithm, where each of the subchannels corresponds to a local feature group related to a discharge mechanism;
a fuzzy reasoning module, configured for independently constructing a fuzzy reasoning model for each of the feature subchannels, and generating channel-level discharge pattern sub-classifiers; and
a dynamic fusion module, configured for dynamically adjusting fusion strategy based on prediction confidence, and performing structural consistency-driven fusion on outputs of the plurality of sub-classifiers.

As one embodiment, the dynamic fusion module has a built-in cross-channel prediction consistency checking mechanism, triggering a confidence re-weighting process for conflicting outputs.

The principle and implementation of the disclosure are expounded by applying specific examples, and the description of the above embodiments is only used to help understand the method and core idea of the disclosure. At the same time, for ordinary skilled in this field, according to the idea of the disclosure, there will be changes in the specific implementation and application scope. In summary, the contents of this description should not be construed as limiting the disclosure.

What is claimed is:

1. An intelligent identification method for partial discharge based on collaborative reasoning, wherein the method comprises:
S1, constructing a multi-scale feature information map of partial discharge measurement data, and extracting inter-dimensional high-order dependencies;
S2, dividing a high-dimensional feature space into a plurality of structural consistency feature subchannels by a structural decomposition algorithm, wherein each of the subchannels corresponds to a local feature group related to a discharge mechanism;
S3, independently constructing a fuzzy reasoning model for each of the feature subchannels, and generating channel-level discharge pattern sub-classifiers;
S4, dynamically adjusting fusion strategy based on prediction confidence, and performing structural consistency-driven fusion on outputs of the plurality of sub-classifiers; and
S5, outputting a final partial discharge type identification result.

2. The intelligent identification method for partial discharge based on collaborative reasoning according to claim 1, wherein in S1, the multi-scale feature information map adopts at least one of mutual information, a GraphLasso algorithm, kernel correlation coefficients or a Copula function to construct inter-dimensional dependencies.

3. The intelligent identification method for partial discharge based on collaborative reasoning according to claim 1, wherein in S2, the structural decomposition algorithm is a sparse spectrum division algorithm, a hierarchical Louvain clustering algorithm or an adaptive multi-channel clustering algorithm.

4. The intelligent identification method for partial discharge based on collaborative reasoning according to claim 1, wherein in S3, the fuzzy reasoning model is constructed by automatically learning fuzzy rule sets and membership function structures.

5. The intelligent identification method for partial discharge based on collaborative reasoning according to claim 1, wherein in S3, the fuzzy reasoning model is capable of being replaced by a sparse Bayesian regression model or an ensemble fuzzy network model.

6. The intelligent identification method for partial discharge based on collaborative reasoning according to claim 1, wherein in S4, the dynamically adjusting fusion strategy comprises:
calculating prediction confidence of each of the sub-classifiers;
performing weighted fusion output according to confidence weight; and
performing fault-tolerant mechanism on inconsistencies among feature channels.

7. The intelligent identification method for partial discharge based on collaborative reasoning according to claim 1, wherein in S4, a fused mechanism is capable of being replaced by a multi-task attention distribution model or a confidence regression network optimization weighting strategy.

8. The intelligent identification method for partial discharge based on collaborative reasoning according to claim 1, wherein in S5, the identification result supports non-exclusive fuzzy classification of unknown or boundary discharge patterns.

9. An intelligent identification system for partial discharge based on collaborative reasoning, comprising:
a feature map construction module, configured for constructing a multi-scale feature information map of partial discharge measurement data, and extracting inter-dimensional high-order dependencies;
a channel dividing module, configured for dividing a high-dimensional feature space into a plurality of structural consistency feature subchannels by a structural decomposition algorithm, wherein each of the subchannels corresponds to a local feature group related to a discharge mechanism;
a fuzzy reasoning module, configured for independently constructing a fuzzy reasoning model for each of the feature subchannels, and generating channel-level discharge pattern sub-classifiers; and
a dynamic fusion module, configured for dynamically adjusting fusion strategy based on prediction confidence, and performing structural consistency-driven fusion on outputs of the plurality of sub-classifiers.

10. The intelligent identification system for partial discharge based on collaborative reasoning according to claim 9, wherein the dynamic fusion module has a built-in cross-channel prediction consistency checking mechanism, triggering a confidence re-weighting process for conflicting outputs.
